(19) United States
(12) Patent Application Publication
(10) Pub. No.: US 2019/0006395 A1
(43) Pub. Date: Jan. 3, 2019

(54) ARRAY SUBSTRATE, METHOD FOR MANUFACTURING THE SAME, AND DISPLAY PANEL

(71) Applicants: BOE Technology Group Co., Ltd., Beijing (CN); Chengdu BOE Optoelectronics Technology Co., Ltd., Chengdu (CN)

(72) Inventors: Dongmei WEI, Beijing (CN); Xiaoxiang HE, Beijing (CN); Zhenxiao TONG, Beijing (CN)

(21) Appl. No.: 15/935,488

(22) Filed: Mar. 26, 2018

(30) Foreign Application Priority Data
Jun. 30, 2017 (CN) 201710525619.8

(51) Int. Cl. H01L 27/12

(52) U.S. Cl. CPC H01L 27/1248; H01L 27/1262

(57) ABSTRACT

The disclosure discloses an array substrate, a method for manufacturing the same, and a display panel, and the array substrate includes a gate, an active layer, a source, and a drain arranged on a base substrate in that order; and further includes: a light blocking layer, where a positive projection of the active layer onto the base substrate overlaps with both of a positive projection of the light blocking layer onto the base substrate, and a positive projection of the gate onto the base substrate; the positive projection of the active layer onto the base substrate lies in positive projections of the light blocking layer and the gate onto the base substrate; and an area of the positive projection of the gate onto the base substrate is smaller than an area of the positive projection of the active layer onto the base substrate.

### CROSS-REFERENCE TO RELATED APPLICATIONS

This application claims the priority to Chinese Patent Application No. 201710525619.8, filed on Jun. 30, 2017, the content of which is hereby incorporated by reference in its entirety.

### FIELD

The present disclosure relates to the field of display technologies, and particularly to an array substrate, a method for manufacturing the same, and a display panel.

### BACKGROUND

As compared with a traditional Cathode Ray Tube (CRT) display, a Liquid Crystal Display (LCD) display can be made small and lightweight, and has been widely applied at present to a TV set, a mobile phone, and a public-information display device. At present in a liquid crystal display panel, voltage can be applied to two electrodes to create an electric field across a liquid crystal layer, and the intensity of the created electric field can be adjusted to thereby adjust the transmittance of light passing through the liquid crystal layer so as to display an image.

### SUMMARY

An embodiment of the disclosure provides an array substrate including: a gate, an active layer, a source, and a drain arranged on a base substrate in that order; wherein the array substrate further includes: a light blocking layer; a positive projection of the active layer onto the base substrate overlaps with both of a positive projection of the light blocking layer onto the base substrate, and a positive projection of the gate onto the base substrate; the positive projection of the active layer onto the base substrate lies in positive projections of the light blocking layer and the gate onto the base substrate; and an area of the positive projection of the gate onto the base substrate is smaller than an area of the positive projection of the active layer onto the base substrate.

An embodiment of the disclosure provides a display panel including the array substrate above according to the embodiment of the disclosure.

An embodiment of the disclosure provides a method for manufacturing the array substrate above according to the embodiment of the disclosure, the method including: forming a pattern of a light blocking layer on a base substrate; and forming patterns including a gate, an active layer, a source, and a drain on the base substrate formed with the pattern of the light blocking layer; wherein a positive projection of the active layer onto the base substrate overlaps with both of a positive projection of the light blocking layer onto the base substrate, and a positive projection of the gate onto the base substrate; the positive projection of the active layer onto the base substrate lies in positive projections of the light blocking layer and the gate onto the base substrate; and an area of the positive projection of the gate onto the base substrate is smaller than an area of the positive projection of the active layer onto the base substrate.

### BRIEF DESCRIPTION OF THE DRAWINGS

FIG. 1 is a schematic structural diagram of a array substrate in the related art;

FIG. 2 is a schematic structural diagram of a array substrate in the related art in a plan view;

FIG. 3 is a schematic diagram of induced charges distributed in a channel area in the related art;

FIG. 4 is a schematic structural diagram of an array substrate according to an embodiment of the disclosure;

FIG. 5 is a schematic structural diagram of the array substrate according to the embodiment of the disclosure in a plan view;

FIG. 6 is a schematic diagram of induced charges distributed in a channel area according to the embodiment of the disclosure;

FIG. 7 is a flow chart of a method for manufacturing an array substrate according to an embodiment of the disclosure; and

FIG. 8A to FIG. 8G are schematic diagrams respectively of a process of manufacturing an array substrate according to an embodiment of the disclosure.

### DETAILED DESCRIPTION OF THE EMBODIMENTS

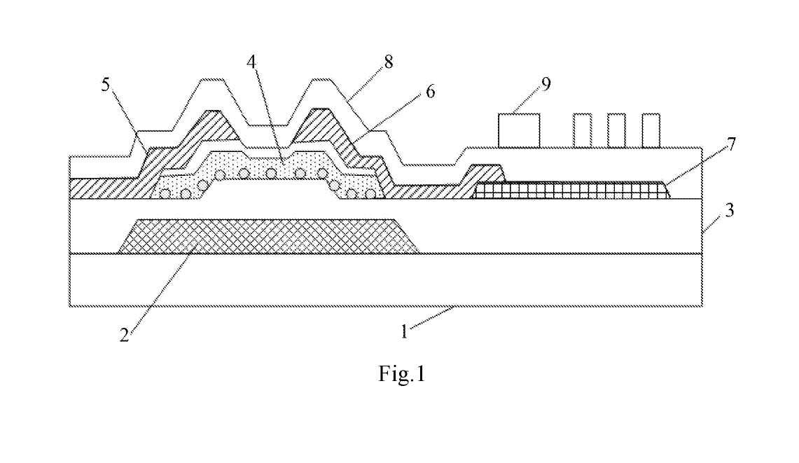

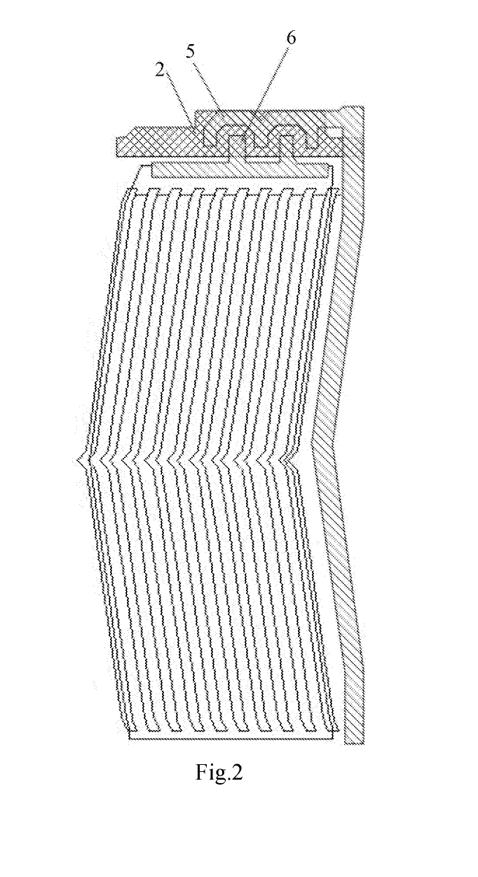

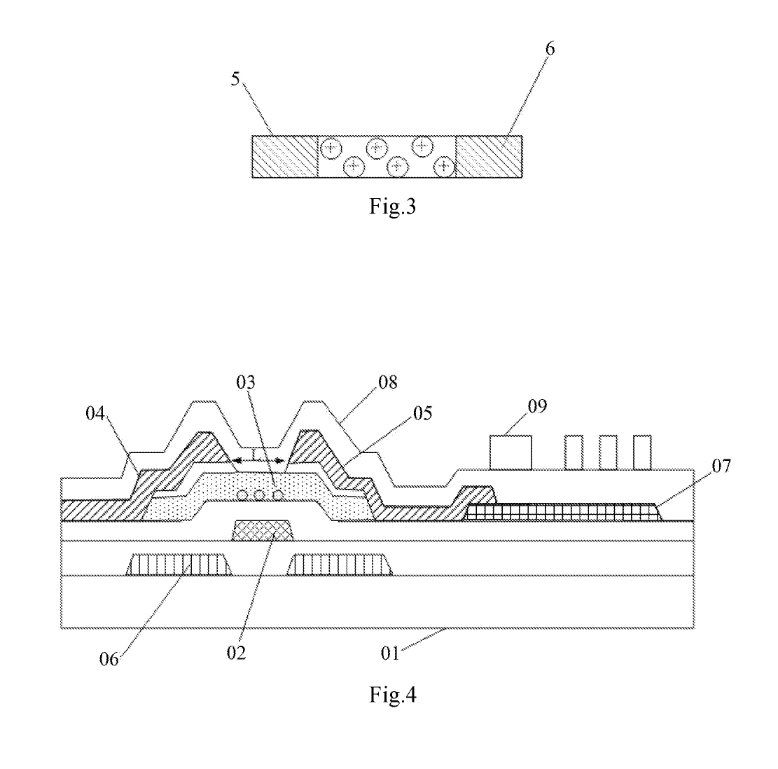

FIG. 1 illustrates a structural diagram of an array substrate in a liquid crystal display panel, where the array substrate generally includes a gate electrode 2, a gate insulation layer 3, an active layer 4, a source electrode 5, a drain electrode 6, a pixel electrode 7, a passivation layer 8, and a common electrode 9 located on a base substrate 1 in that order, where generally the gate electrode 2, the active layer 4, the source electrode 5 and the drain electrode 6 constitute a Thin Film Transistor (TFT) for controlling each pixel switch. Since there is a large overlapping area between the gate electrode, and the source and drain electrodes in each TFT in the related art, there may be such a large parasitic capacitance between the gate electrode, and the source and drain electrodes that comes with a high load while the liquid crystal display panel is being driven to display, thus resulting in high power consumption of the display panel as a whole. Furthermore as illustrated in FIG. 1, when the TFT is switched off, there are a lot of charges induced in a channel area corresponding to the gate electrode; and as illustrated in FIG. 2, there is a large overlapping area between the gate electrode 2, and the source and drain electrodes 5 and 6, so as illustrated in FIG. 3, the induced charges may contact with metal of the source and drain electrodes 5 and 6 on both sides thereof, so a current pathway is formed, thus resulting in leakage on the sidewalls of the display panel.

In view of this, it is highly desirable for those skilled in the art to lower power consumption of the display panel, and to improve a display effect of the display panel.

Particular implementations of the array substrate, the method for manufacturing the same, and the display panel according to the embodiments of the disclosure will be described below in details with reference to the drawings.

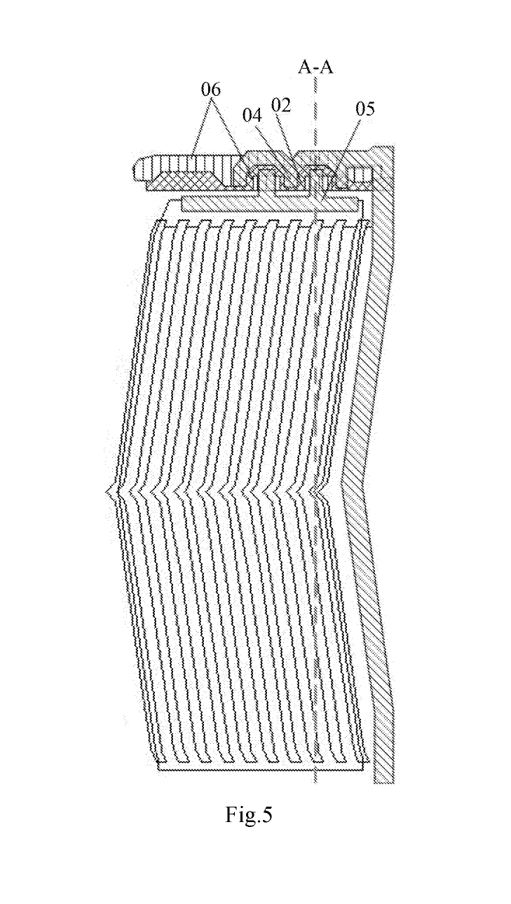

An embodiment of the disclosure provides an array substrate as illustrated in FIG. 4, the array substrate can include a gate 02, an active layer 03, a source 04, and a drain 05 arranged on a base substrate 01 in that order; and the array substrate can further include: a light blocking layer 06, where a positive projection of the active layer 03 onto the base substrate 01 overlaps with both of a positive projection of the light blocking layer 06 onto the base substrate 01, and a positive projection of the gate 02 onto the base substrate 01; the positive projection of the active layer 03 onto the base substrate 01 lies in the area of the positive projections of the light blocking layer 06 and the gate 02 onto the base substrate 01; and the area of the positive projection of the gate 02 onto the base substrate 01 is smaller than the area of the positive projection of the active layer 03 onto the base substrate 01.

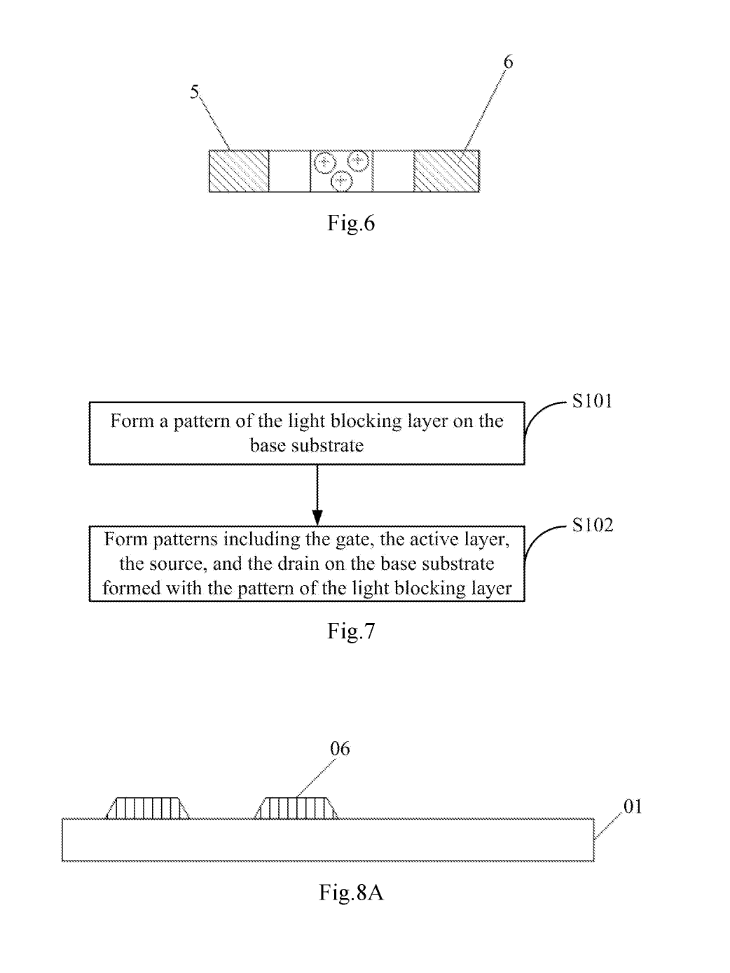

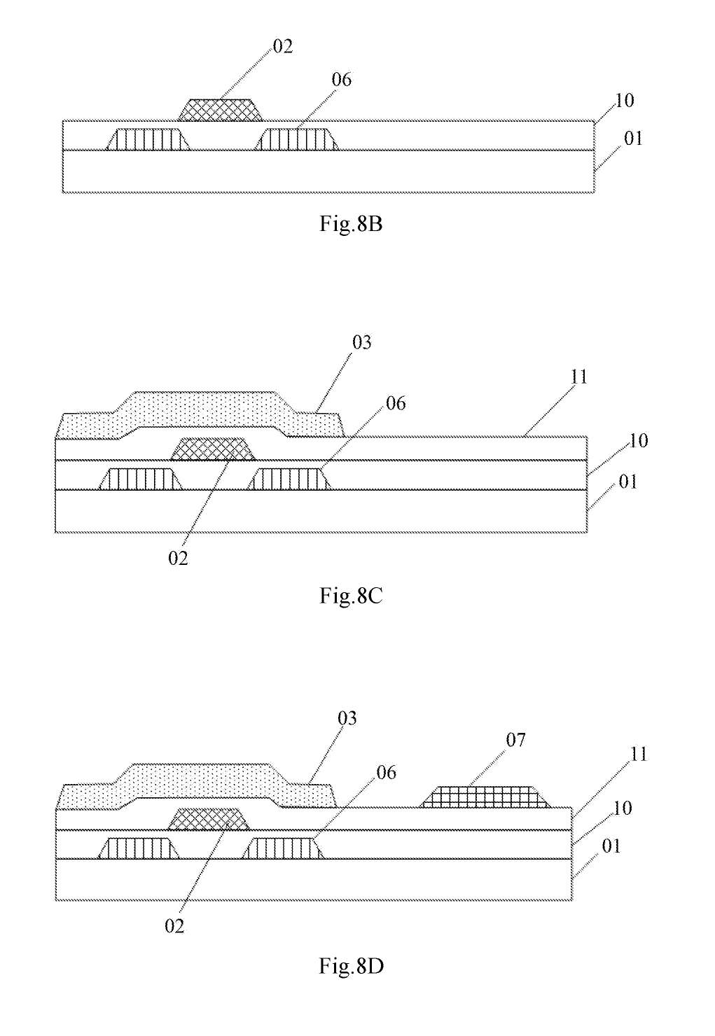

In the array substrate above according to the embodiment of the disclosure, the light blocking layer 06 is arranged on the base substrate so that there are overlapping areas between the light blocking layer 06 and the active layer 03, and between the gate 02 and the active layer 03 as illustrated in FIG. 5 (FIG. 4 illustrates a sectional view of the top view in FIG. 5 along the line A-A), so that the overlapping area between the gate and the active layer can be reduced, and further the overlapping areas between the gate, and source and drain electrodes can be reduced, that is, the additional light blocking layer can be arranged to thereby reduce the width of the gate so that the overlapping areas between the gate, and the source and drain electrodes can be reduced, and parasitic capacitance between the gate, and the source and drain electrodes can be reduced, thus lowering power consumption of a display panel; and also the positive projection of the active layer onto the base substrate can be arranged to lie in the area of the positive projection of the gate and the light blocking layer onto the base substrate, so that the active layer can be completely shielded by the gate and the light blocking layer in the direction perpendicular to the base substrate to thereby avoid photo-induced carriers, i.e., optical leakage, from being generated due to optical induction of the active layer. Furthermore as illustrated in FIG. 6, after the width of the gate is reduced, there are charges induced at the active layer only in those areas exactly facing the gate, so that the inducted charges can be alleviated from directly contacting with the source and the drain, to thereby alleviate leakage in holes so as to improve leakage on the sidewalls of the display panel.

In a particular implementation, in the array substrate above according to the embodiment of the disclosure, the positive projection of the gate onto the base substrate can be arranged to partially overlap or not overlap with the positive projection of the light blocking layer onto the base substrate. Particularly in the array substrate above according to the embodiment of the disclosure, the gate can be arranged not to overlap with the light blocking layer, so that the overlapping areas of the gate with the source and the drain do not overlap with the overlapping areas of the light blocking layer with the source and the drain. In this way, the overlapping areas with the source and the drain can be shared by the light blocking layer and the gate to thereby reduce the width of the gate so as to reduce the overlapping areas between the gate, and the source and the drain, thus reducing parasitic capacitance between the gate, and the source and the drain, thus lowering power consumption of the display panel; and also the light blocking layer does not overlap with the gate, so that parasitic capacitance can be prevented from being formed between the light blocking layer and the gate.

In a particular implementation, in the array substrate above according to the embodiment of the disclosure, the light blocking layer can be located between the base substrate and the gate, and the shape of the source can be arranged in a U-shape. Particularly in the array substrate in the related art, as illustrated in FIG. 2, the majority areas of two U-shaped sources 5 connected in series overlap with the gate 02, so that there may be such a large overlapping area between the gate and the source that results in a large parasitic capacitance. The light blocking layer is arranged in the embodiment of the disclosure as illustrated in FIG. 5, where the light blocking layer 06 can be arranged surrounding its corresponding gate 02 to thereby shield the active layer 03, and in this way, the gate 02 may not be made large to overlap with the U-shaped source 04, thus reducing effectively parasitic capacitance between the gate and the source electrode so as to lower power consumption of the display panel.

In a particular implementation, in the array substrate above according to the embodiment of the disclosure, the material of the light blocking layer can be a metal material through which no light can be transmitted. Particularly in the array substrate above according to the embodiment of the disclosure, the light blocking layer can be made of a metal material through which no light can be transmitted, to thereby shield the active layer from being affected by light rays from the outside so as to prevent photo-induced carriers from being generated by the active layer, and also reduce the overlapping areas between the gate, and the source and drain electrodes so as to reduce parasitic capacitance between the gate, and the source and drain electrodes, thus lowering power consumption of the display panel.

In a particular implementation, in the array substrate above according to the embodiment of the disclosure, the light blocking layer can be floating; or a corresponding signal can be input to the light blocking layer, and for example, a common electrode signal can be input to the light blocking layer which is a common electrode line, or a touch signal can be input to the light blocking layer. As needed in reality, the light blocking layer can be fabricated together with another functional layer, and for example, the light blocking layer can be fabricated together with a common electrode line or a touch lead in the same patterning process, the embodiment of the disclosure will not be limited thereto.

In a particular implementation, in the array substrate above according to the embodiment of the disclosure, as illustrated in FIG. 4, the array substrate can further include a pixel electrode 07, a passivation layer 08 and a common electrode 09, where the pixel electrode 07 is arranged at the same layer as the active layer, and electrically connected with the drain 05; the passivation layer 08 is located above the source 04 and the drain 05; and the common electrode 09 is located above the passivation layer 08. Particularly the array substrate above according to the embodiment of the disclosure further includes a plurality of requisite layer structures, e.g., pixel electrodes, passivation layers, common electrodes, etc., for driving and displaying functions of the array substrate. Functional and structural designs of the respective layers will be the same as those in the related art, so a repeated description thereof will be omitted here.

Based upon the same inventive idea, an embodiment of the disclosure further provides a display panel including the array substrate above according to the embodiment of the disclosure. The display panel can be applicable to a mobile phone, a tablet computer, a TV set, a monitor, a notebook computer, a digital camera, a navigator, or any other product or component with a display function. Since the display panel addresses the problem under a similar principle to the array substrate, reference can be made to the implementation of the array substrate above for an implementation of the display panel, so a repeated description thereof will be omitted here.

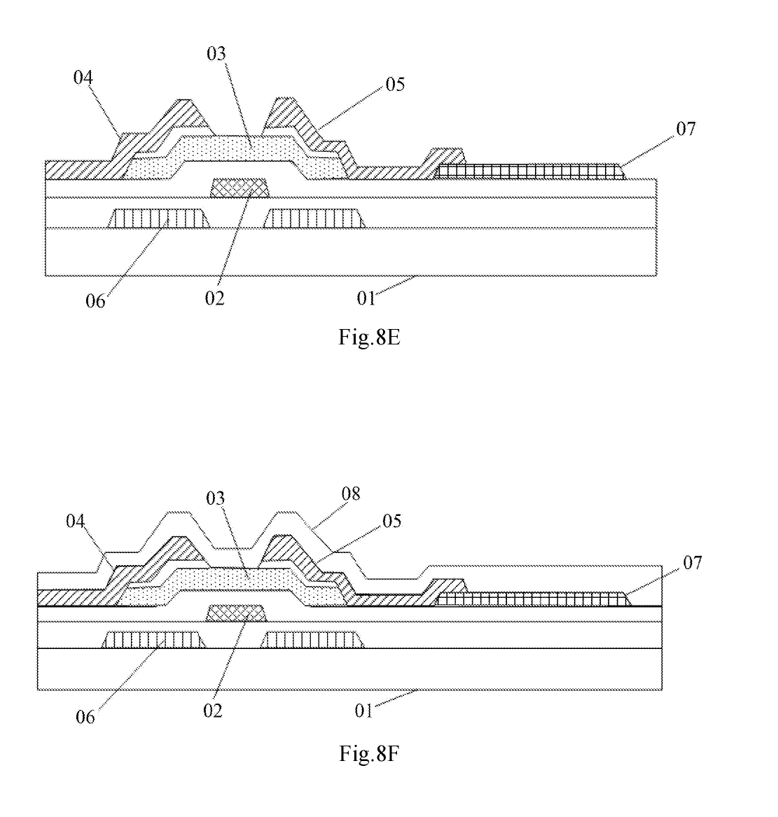

Based upon the same inventive idea, an embodiment of the disclosure further provides a method for manufacturing the array substrate above according to the embodiment of the disclosure, and as illustrated in FIG. 7, the method can particularly include the following steps.

S101 is to form a pattern of the light blocking layer on the base substrate.

S102 is to form patterns including the gate, the active layer, the source, and the drain on the base substrate formed with the pattern of the light blocking layer.

Where a positive projection of the active layer onto the base substrate overlaps with both of a positive projection of the light blocking layer onto the base substrate, and a positive projection of the gate onto the base substrate; and the positive projection of the active layer onto the base substrate lies in positive projections of the light blocking layer and the gate onto the base substrate.

The area of the positive projection of the gate onto the base substrate is smaller than the area of the positive projection of the active layer onto the base substrate.

The manufacturing method above according to the embodiment of the disclosure can further include fabricating the plurality of requisite layers including the pixel electrode, the passivation layer and the common electrode, and particularly the respective layers are fabricated particularly as follows.

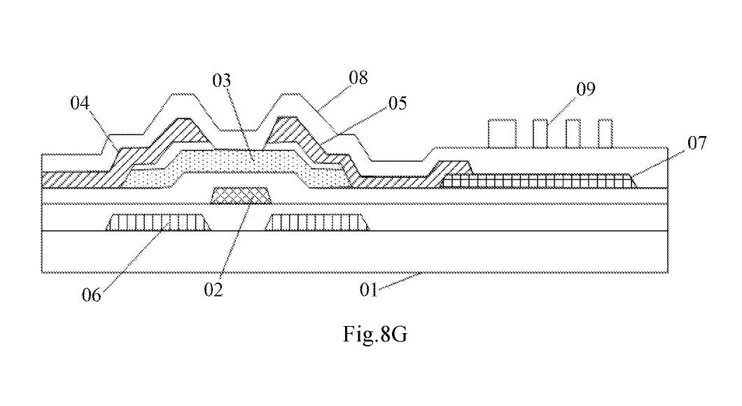

The first step is to form the pattern of the light blocking layer 06 on the base substrate 01 in a patterning process, where FIG. 8A illustrates the base substrate formed with the light blocking layer.

The second step is to form the patterns of the gate 02 and the insulation layer 10 on the base substrate 01 formed with the light blocking layer 06 in a patterning process, where FIG. 8B illustrates the base substrate formed with the gate.

The third step is to form the patterns of the active layer 03 and the gate insulation layers 11 on the base substrate 01 formed with the gate 02 in a patterning process, where FIG. 8C illustrates the base substrate formed with the active layer.

The fourth step is to form the pattern of the pixel electrode 07 on the base substrate 01 formed with the active layer 03 in a patterning process, where FIG. 8D illustrates the base substrate formed with the pixel electrode.

The fifth step is to form the patterns of the source 04 and the drain 05 on the base substrate 01 formed with the pixel electrode 07 in a patterning process, where FIG. 8E illustrates the base substrate formed with the source and the drain.

The sixth step is to form the pattern of the passivation layer 08 on the base substrate 01 formed with the source 04 and the drain 05 in a patterning process, where FIG. 8F illustrates the base substrate formed with the passivation layer.

The seventh step is to form the pattern of the common electrode 09 on the base substrate 01 formed with the passivation layer 08 in a patterning process, where FIG. 8G illustrates the base substrate formed with the common electrode.

In the manufacturing method above according to the embodiment of the disclosure, the light blocking layer is fabricated on the base substrate so that there are overlapping areas between the light blocking layer and the active layer, and between the gate and the active layer, and in this way, the overlapping area between the gate and the active layer can be reduced, and further the overlapping areas between the gate and the source and drain electrodes can be reduced, that is, the additional light blocking layer can be arranged to thereby reduce the width of the gate so that the overlapping areas between the gate and the source and drain electrodes can be reduced, and parasitic capacitance between the gate and the source and drain electrodes can be reduced, thus lowering power consumption of the display panel; and also the positive projection of the active layer onto the base substrate can be arranged to lie in the area of the positive projections of the gate and the light blocking layer onto the base substrate, so that the active layer can be completely shielded by the gate and the light blocking layer in the direction perpendicular to the base substrate to thereby avoid photo-induced carriers, i.e., optical leakage, from being generated due to optical induction of the active layer.

In a particular implementation, in the manufacturing method above according to the embodiment of the disclosure, the positive projection of the gate onto the base substrate can be arranged to partially overlap or not overlap with the positive projection of the light blocking layer onto the base substrate. Particularly the gate can be arranged not to overlap with the light blocking layer, so that the overlapping areas of the gate with the source and the drain do not overlap with the overlapping areas of the light blocking layer with the source and the drain. In this way, the overlapping areas with the source and the drain can be shared by the light blocking layer and the gate to thereby reduce the width of the gate so as to reduce the overlapping areas between the gate, and the source and the drain, thus reducing parasitic capacitance between the gate, and the source and the drain, thus lowering power consumption of the display panel, thus lowering power consumption of the display panel; and also the light blocking layer does not overlap with the gate, so that parasitic capacitance can be prevented from being formed between the light blocking layer and the gate.

The embodiments of the disclosure provide an array substrate, a method for manufacturing the same, and a display panel, and the array substrate includes a gate, an active layer, a source and a drain arranged on a base substrate in that order; and the array substrate further includes: a light blocking layer, where positive projection of the active layer onto the base substrate overlaps with both of positive projection of the light blocking layer onto the base substrate, and positive projection of the gate onto the base substrate; the positive projection of the active layer onto the base substrate lies in the positive projections of the light blocking layer and the gate onto the base substrate; and the area of the positive projection of the gate onto the base substrate is smaller than the area of the positive projection of the active layer onto the base substrate. In this way, in the embodiments of the disclosure, the light blocking layer is arranged on the base substrate so that there are overlapping areas between the light blocking layer and the active layer, and between the gate and the active layer, so that the overlapping area between the gate and the active layer can be reduced, and further the overlapping areas between the gate and the source and drain electrodes can be reduced, that is, the additional light blocking layer can be arranged to thereby reduce the width of the gate so that the overlapping areas between the gate and the source and drain electrodes can be reduced, and parasitic capacitances between the gate and the source and drain electrodes can be reduced, thus lowering power consumption of the display panel; and also the positive projection of the active layer onto the base substrate can be arranged to lie in the area of the positive projection of the gate and the light blocking layer onto the base substrate, so that the active layer can be completely shielded by the gate and the light blocking layer in the direction perpendicular to the base substrate to thereby avoid photo-induced carriers, i.e., optical leakage, from being generated due to optical induction of the active layer.

Evidently those skilled in the art can make various modifications and variations to this disclosure without departing from the spirit and scope of this disclosure. Thus this disclosure is also intended to encompass these modifications and variations thereto so long as the modifications and variations come into the scope of the claims appended to this disclosure and their equivalents.

1. An array substrate, comprising a gate, an active layer, a source, and a drain arranged on a base substrate in that order; wherein the array substrate further comprises: a light blocking layer;
a positive projection of the active layer onto the base substrate overlaps with both of a positive projection of the light blocking layer onto the base substrate, and a positive projection of the gate onto the base substrate;
the positive projection of the active layer onto the base substrate lies in positive projections of the light blocking layer and the gate onto the base substrate; and
an area of the positive projection of the gate onto the base substrate is smaller than an area of the positive projection of the active layer onto the base substrate.

2. The array substrate according to claim 1, wherein the positive projection of the gate onto the base substrate partially overlaps, or does not overlap, with the positive projection of the light blocking layer onto the base substrate.

3. The array substrate according to claim 1, wherein the light blocking layer is located between the base substrate and the gate.

4. The array substrate according to claim 1, wherein a shape of the source is a U-shape.

5. The array substrate according to claim 1, wherein a material of the light blocking layer is a metal material.

6. The array substrate according to claim 1, wherein the array substrate further comprises a pixel electrode, a passivation layer, and a common electrode;
the pixel electrode is arranged at the same layer as the active layer, and electrically connected with the drain;
the passivation layer is located above the source and the drain; and
the common electrode is located above the passivation layer.

7. A display panel, comprising an array substrate, the array substrate comprising a gate, an active layer, a source, and a drain arranged on a base substrate in that order; wherein the array substrate further comprises: a light blocking layer;
a positive projection of the active layer onto the base substrate overlaps with both of a positive projection of the light blocking layer onto the base substrate, and a positive projection of the gate onto the base substrate;
the positive projection of the active layer onto the base substrate lies in positive projections of the light blocking layer and the gate onto the base substrate; and
an area of the positive projection of the gate onto the base substrate is smaller than an area of the positive projection of the active layer onto the base substrate.

8. The display panel according to claim 7, wherein the positive projection of the gate onto the base substrate partially overlaps, or does not overlap, with the positive projection of the light blocking layer onto the base substrate.

9. The display panel according to claim 7, wherein the light blocking layer is located between the base substrate and the gate.

10. The display panel according to claim 7, wherein a shape of the source is a U-shape.

11. The display panel according to claim 7, wherein a material of the light blocking layer is a metal material.

12. The display panel according to claim 7, wherein the array substrate further comprises a pixel electrode, a passivation layer, and a common electrode;
the pixel electrode is arranged at the same layer as the active layer, and electrically connected with the drain;
the passivation layer is located above the source and the drain; and
the common electrode is located above the passivation layer.

13. A method for manufacturing the array substrate according to claim 1, the method comprising:
forming a pattern of a light blocking layer on a base substrate; and
forming patterns comprising a gate, an active layer, a source, and a drain on the base substrate formed with the pattern of the light blocking layer;
wherein a positive projection of the active layer onto the base substrate overlaps with both of a positive projection of the light blocking layer onto the base substrate, and a positive projection of the gate onto the base substrate;
the positive projection of the active layer onto the base substrate lies in positive projections of the light blocking layer and the gate onto the base substrate; and
an area of the positive projection of the gate onto the base substrate is smaller than an area of the positive projection of the active layer onto the base substrate.

14. The manufacturing method according to claim 13, wherein the positive projection of the gate onto the base substrate partially overlaps, or does not overlap, with the positive projection of the light blocking layer onto the base substrate.

15. The manufacturing method according to claim 13, wherein the method further comprises:
forming patterns comprising a pixel electrode, a passivation layer, and a common electrode on the base substrate formed with the pattern of the light blocking layer.

16. The manufacturing method according to claim 14, wherein the method further comprises:
forming patterns comprising a pixel electrode, a passivation layer, and a common electrode on the base substrate formed with the patterns of the light blocking layer.
